(19) United States
(12) Patent Application Publication
(10) Pub. No.: US 2017/0194133 A1
(43) Pub. Date: Jul. 6, 2017

(54) Electrode Tip for ARC Lamp

(71) Applicant: Mattson Technology, Inc., Fremont, CA (US)

(72) Inventors: Markus Lieberer, Augsburg (DE); Christian Seifert, Ulm (DE); Rolf Bremensdorfer, Bibertal (DE)

(21) Appl. No.: 15/380,221

(22) Filed: Dec. 15, 2016

Related U.S. Application Data
(60) Provisional application No. 62/272,921, filed on Dec. 30, 2015.

(51) Int. Cl. H01J 61/073; H01L 21/268; H05H 1/48; H05B 3/00; H05B 3/03; H01L 21/67; H01J 61/52

(52) U.S. Cl. CPC H01J 61/0732; H01L 21/67115; H01L 21/268; H01J 61/526; H05B 3/0047; H05B 3/03; H05H 1/48

(57) ABSTRACT

Electrode tips for arc lamps for use in, for instance, a millisecond anneal system are provided. In one example implementation, an electrode for an arc lamp can have an electrode tip. The surface of the electrode tip can have one or more grooves to reduce the transportation of molten material across the surface of the electrode tip. The electrode can include an interface between the electrode tip and a heat sink. The interface can have a shape designed to have a desired lateral temperature distribution across the surface of the electrode tip.

### PRIORITY CLAIM

The present application claims the benefit of priority of U.S. Provisional Application Ser. No. 62/272,921, filed on Dec. 30, 2015, entitled “Lamp Electrode Tip for a Millisecond Anneal System.”

### FIELD

The present disclosure relates generally to arc lamps used, for instance, in and millisecond anneal thermal processing chambers used for processing substrates.

### BACKGROUND

Millisecond anneal systems can be used for semiconductor processing for the ultra-fast heat treatment of substrates, such as silicon wafers. In semiconductor processing, fast heat treatment can be used as an anneal step to repair implant damage, improve the quality of deposited layers, improve the quality of layer interfaces, to activate dopants, and to achieve other purposes, while at the same time controlling the diffusion of dopant species.

Millisecond, or ultra-fast, temperature treatment of semiconductor substrates can be achieved using an intense and brief exposure of light to heat the entire top surface of the substrate at rates that can exceed 10⁴° C. per second. The rapid heating of just one surface of the substrate can produce a large temperature gradient through the thickness of the substrate, while the bulk of the substrate maintains the temperature before the light exposure. The bulk of the substrate therefore acts as a heat sink resulting in fast cooling rates of the top surface.

### SUMMARY

Aspects and advantages of embodiments of the present disclosure will be set forth in part in the following description, or may be learned from the description, or may be learned through practice of the embodiments.

One example aspect of the present disclosure is directed to a millisecond anneal system. The system can include a processing chamber for thermally treating a semiconductor substrate using a millisecond anneal process. The system can include one or more arc lamp heat sources. Each of the one or more arc lamp heat sources can include a plurality of electrodes for generating an arc through a gas in the arc lamp to generate a plasma. At least one of the plurality of electrodes has an electrode tip (e.g., formed from tungsten) having a surface with at least one groove to reduce lateral transportation of molten material across the surface of the electrode tip.

Another example aspect of the present disclosure is directed to an arc lamp. The arc lamp can include a plurality of electrodes and one or more inlets configured to receive water to be circulated through the arc lamp during operation. The one or more inlets can be configured to receive a gas. During operation of the arc lamp the gas can be converted to a plasma during an arc discharge between the plurality of electrodes. At least one of the plurality of electrodes can have an electrode tip. The electrode tip can have a surface with at least one groove to reduce lateral transportation of molten material across the surface of the electrode tip.

Another example aspect of the present disclosure is directed to an arc lamp. The arc lamp can include a plurality of electrodes and one or more inlets configured to receive water to be circulated through the arc lamp during operation. The one or more inlets can be configured to receive a gas. During operation of the arc lamp the gas can be converted to a plasma during an arc discharge between the plurality of electrodes. At least one of the plurality of electrodes can have an electrode tip and a heat sink. The electrode can have an interface between the electrode tip and the heat sink that is concave or convex.

Variations and modification can be made to the example aspects of the present disclosure. Other example aspects of the present disclosure are directed to systems, methods, devices, and processes for thermally treating a semiconductor substrate.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example millisecond heating profile according to example embodiments of the present disclosure;

FIG. 2 depicts an example temperature measurement system for a millisecond anneal system according to example embodiments of the present disclosure;

FIG. 3 depicts an example perspective view of a portion of an example millisecond anneal system according to example embodiments of the present disclosure;

FIG. 4 depicts an exploded view of an example millisecond anneal system according to example embodiments of the present disclosure;

FIG. 5 depicts a cross-sectional view of an example millisecond anneal system according to example embodiments of the present disclosure;

FIG. 6 depicts example lamps used in a millisecond anneal system according to example embodiments of the present disclosure;

FIG. 7 depicts example edge reflectors used in a wafer plane plate of a millisecond anneal system according to example embodiments of the present disclosure;

FIG. 8 depicts example wedge reflectors that can be used in a millisecond anneal system according to example embodiments of the present disclosure;

FIG. 9 depicts an example arc lamp that can be used in a millisecond anneal system according to example embodiments of the present disclosure;

FIGS. 10-11 depict the operation of an example arc lamp according to example embodiments of the present disclosure;

FIG. 12 depicts a cross-sectional view of an example electrode according to example embodiments of the present disclosure;

FIG. 13 depicts an example closed loop system for supplying water and argon gas to example arc lamps used in a millisecond anneal system according to example embodiments of the present disclosure;

FIG. 14 depicts a front view of an example electrode tip in an arc lamp according to example embodiments of the present disclosure;

FIG. 15 depicts a surface of an electrode tip according to example embodiments of the present disclosure;

FIG. 16 depicts a surface of an electrode tip according to example embodiments of the present disclosure;

FIG. 17 depicts a surface of an electrode tip according to example embodiments of the present disclosure;

FIG. 18 depicts a surface of an electrode tip according to example embodiments of the present disclosure; and

FIG. 19(a)-19(d) depicts example shapes of the tungsten-copper interface in an electrode for an arc lamp to influence lateral temperature distribution for the electrode according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

### Overview

Example aspects of the present disclosure are directed to extending the lifetime of and arc lamp, specifically, the anode electrode of an arc lamp used in, for instance, a millisecond anneal system. Aspects of the present disclosure will be discussed with reference to arc lamps used in conjunction with millisecond anneal systems for purposes of illustration and discussion. Those of ordinary skill in the art, using the disclosures provided herein, will understand that aspects of the present disclosure can be used with arc lamps in other applications, such as for processing of metals (e.g., melting a surface of steel), and other applications.

In addition, aspects of the present disclosure are discussed with reference to a “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. The use of the term “about” in conjunction with a numerical value is intended to refer to within 10% of the stated numerical value.

Millisecond, or ultra-fast, thermal treatment of semiconductor wafers can be achieved using an intense and brief exposure of light (e.g., a “flash”) to heat the entire top surface of the wafer at rates that can exceed 10⁴° C. per second. A typical heat treatment cycle can include: (a) loading a cold semiconductor substrate into the chamber; (b) purging the chamber with, for instance, nitrogen gas (atmospheric pressure); (c) heating the semiconductor substrate to an intermediate temperature Ti; (d) millisecond heating by flash exposure of the top surface of the semiconductor substrate, while the bulk of the wafer remains at Tᵢ; (e) rapid cool down by conductive cooling of the top surface of the semiconductor substrate with the bulk of the semiconductor substrate being the conductively coupled heat sink; (f) slow cool down of the bulk of the semiconductor substrate by thermal radiation and convection, with the process gas at atmospheric pressure as cooling agent; and (g) transport the semiconductor substrate back to the cassette.

As discussed in detail below, arc lamps can be used to both heat the semiconductor substrate to an intermediate temperature Tᵢ and to provide millisecond heating by flash. Continuous mode arc lamps located at the bottom side of the millisecond anneal processing chamber can be used to heat the semiconductor substrate to the intermediate temperature Tᵢ. Flash arc lamps located at the top side of the millisecond anneal processing chamber can provide for the flash heating of the semiconductor substrate.

In some embodiments, the continuous mode lamps, like the flash arc lamps, can be open flow arc lamps, where pressurized Argon gas is converted into a high pressure Argon plasma during the arc discharge. The arc discharge takes place between a negatively charged cathode and a positively charge anode spaced, for instance, about 300 mm apart. As soon as the voltage between the electrodes reaches the breakdown voltage (e.g., about 30 kV) of Argon, a stable, low inductive Argon plasma is formed which emits light in the visible and UV range of the spectrum.

The amount of light energy the lamp radiates is controlled by controlling the current through the arc. In order to sustain the arc, the lamp can be operated in an idle mode with a current of about 20 A and corresponding electrical power of about 3.8 kW. To provide light, the lamp current can be increased to about 500 A (an electrical power of about 175 kW). About 50% of the electrical power is converted into light. During the heat treatment of the wafer, the lamp current can be varying between the idle condition and the high current condition. Lamps are in idle mode during wafer transport and cooling.

In the arc lamps, the plasma can be contained within a quartz tube envelope which is water cooled from the inside by a water wall. The water wall is injected at high flow rates on the cathode end of the lamp and exhausted at the anode end. The same is true for the Argon gas, which is also entering the lamp at the cathode side and exhausted from the anode side. The water forming the water wall is injected perpendicular to the lamp axis such that the centrifugal action generates a water vortex. Hence, along the center line of the lamp a channel is formed for the Argon gas. The Argon gas column is rotating in the same direction as the water wall. Once a plasma has formed, the water wall is protecting the quartz tube and confining the plasma to the center axis. Only the water wall and the electrodes are in direct contact with the high energy plasma.

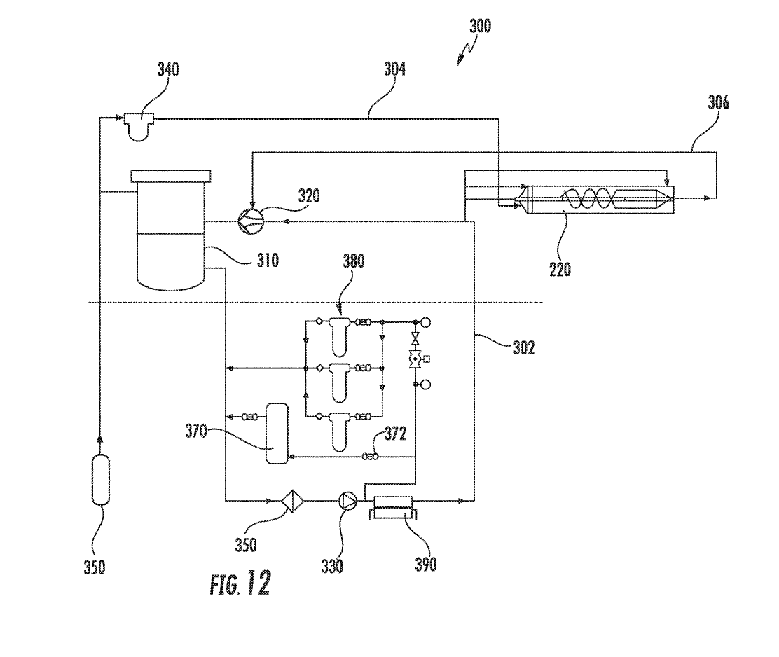

As the electrodes experience a high heat load, the tips are made from tungsten, which is fused to a water cooled copper heat sink. The copper heat sink constitutes one part of the internal cooling system of the electrodes, with the other part being located in the brass base of the electrode. FIG. 12 depicts an example cooling system for cooling an anode electrode for an arc lamp according to example embodiments of the present disclosure. In some embodiments, the water cooling channels in the cooling system for the anode electrode can be circular or rounded in cross-section to facilitate transportation of steam bubbles from a surface of the anode.

At high currents (e.g., greater than about 300 A), the melting of the top layer of the tungsten tip of the electrode can be difficult to avoid. The tungsten tip of the anode electrode can be exposed to a high energy, high temperature, high pressure plasma. The tip reaches the melting temperature of tungsten (e.g., about 3422° C.), whereas the interface to the copper heat sink is at about 150° C. Hence, there can be a large thermal gradient through the thickness of the tungsten tip.

At the same time, there can also be lateral temperature gradient across the surface of the tip. Melting of tungsten occurs first in the center region and along the perimeter of the tip, the edge region. The high velocity of Argon gas acting on the tip, exerts a lateral force to the molten tungsten forming in the center. Molten tungsten is transported as drops to the edge and the center is thinned. At the edge perimeter the drops are getting pinned due to the sudden increase in contact angle (e.g., greater than about 180°).

During the idle mode phases the molten tungsten solidifies and beads are formed. Large size bead formation at the edge typically disturbs the gas and water flow around the anode, increasing the wear rate. For each heat treatment cycle the tungsten beads undergo melting and solidification. Large drops grow at the expense of the smaller drops. The high velocity gas flow exerts a higher force on large drops increasing the amount of material transported to the edge. The center thinning and the large bead formation on the edge is therefore accelerating over time.

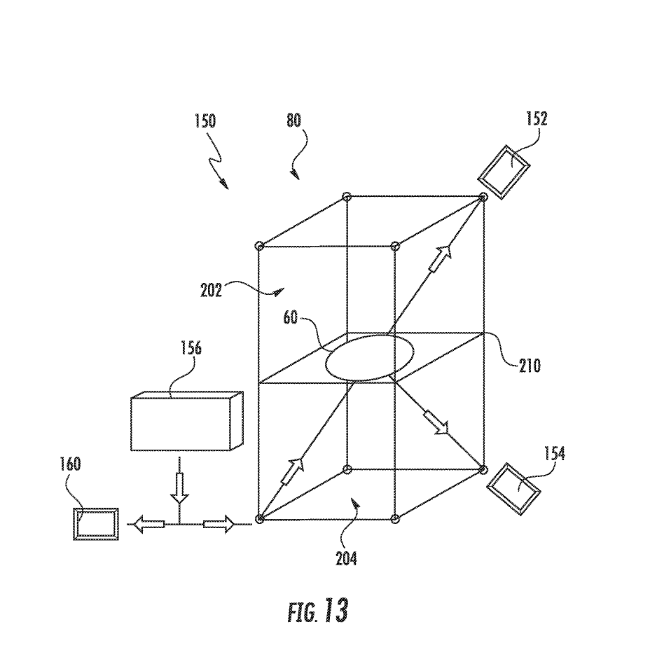

FIG. 14 depicts an illustration of the two regions of the electrode tip 232 where melting occurs. The melting occurs first at the center region 302. The high gas flow rate exerts a lateral force on the molten tungsten forming in the center of the tip as shown in the image on the right, resulting in molten material being transported to the edge 304 as indicated by the arrows in FIG. 14.

According to example embodiments of the present disclosure, the geometry of the surface of the electrode tip is modified to reduce transportation of molten tungsten to the lateral edges. More particularly, the surface of the electrode tip can have one or more grooves to prevent the lateral transport of molten material.

For instance, in one example embodiment, a millisecond anneal system can include a processing chamber for thermally treating a semiconductor substrate using a millisecond anneal process. The system can include one or more arc lamp heat sources. Each of the one or more arc lamp heat sources can include a plurality of electrodes for generating an arc through a gas in the arc lamp to generate a plasma. At least one of the plurality of electrodes has an electrode tip (e.g., formed from tungsten) having a surface with at least one groove to reduce lateral transportation of molten material across the surface of the electrode tip.

In some embodiments, the at least one groove has a rim configured to act as a barrier to reduce the lateral transportation of molten material across the surface of the electrode tip. In some embodiments, the at least one groove includes a circular groove. In some embodiments, the at least one groove includes a plurality of concentric circular grooves. In some embodiments, the at least one groove includes a plurality of intersecting linear grooves. The intersecting linear grooves can form a square grid pattern. The intersecting linear grooves can form a triangular grid pattern.

In some embodiments, the electrode has an interface between the electrode tip (e.g., tungsten electrode tip) and a heat sink (e.g., copper heat sink). The interface can have a concave shape in some embodiments. The interface can have convex shape in some embodiments.

Another example aspect of the present disclosure is directed to an arc lamp. The arc lamp can include a plurality of electrodes and one or more inlets configured to receive water to be circulated through the arc lamp during operation. The one or more inlets can be configured to receive a gas. During operation of the arc lamp the gas can be converted to a plasma during an arc discharge between the plurality of electrodes. At least one of the plurality of electrodes can have an electrode tip. The electrode tip can have a surface with at least one groove to reduce lateral transportation of molten material across the surface of the electrode tip.

In some embodiments, the at least one groove has a rim configured to act as a barrier to reduce the lateral transportation of molten material across the surface of the electrode tip. In some embodiments, the at least one groove includes a circular groove. In some embodiments, the at least one groove includes a plurality of concentric circular grooves. In some embodiments, the at least one groove includes a plurality of intersecting linear grooves. The intersecting linear grooves can form a square grid pattern. The intersecting linear grooves can form a triangular grid pattern.

In some embodiments, the electrode has an interface between the electrode tip (e.g., tungsten electrode tip) and a heat sink (e.g., copper heat sink). The interface can have a concave shape in some embodiments. The interface can have convex shape in some embodiments.

Another example aspect of the present disclosure is directed to an arc lamp. The arc lamp can include a plurality of electrodes and one or more inlets configured to receive water to be circulated through the arc lamp during operation. The one or more inlets can be configured to receive a gas. During operation of the arc lamp the gas can be converted to a plasma during an arc discharge between the plurality of electrodes. At least one of the plurality of electrodes can have an electrode tip and a heat sink. The electrode can have an interface between the electrode tip and the heat sink that is concave or convex.

In some embodiments, the interface can be a faceted concave interface. In some embodiments, the interface can be a rounded concave interface. In some embodiments, the interface can be a faceted convex interface. In some embodiments, the interface can be a faceted concave interface. In some embodiments, the electrode tip includes tungsten and the heat sink includes copper.

### Example Millisecond Anneal Systems

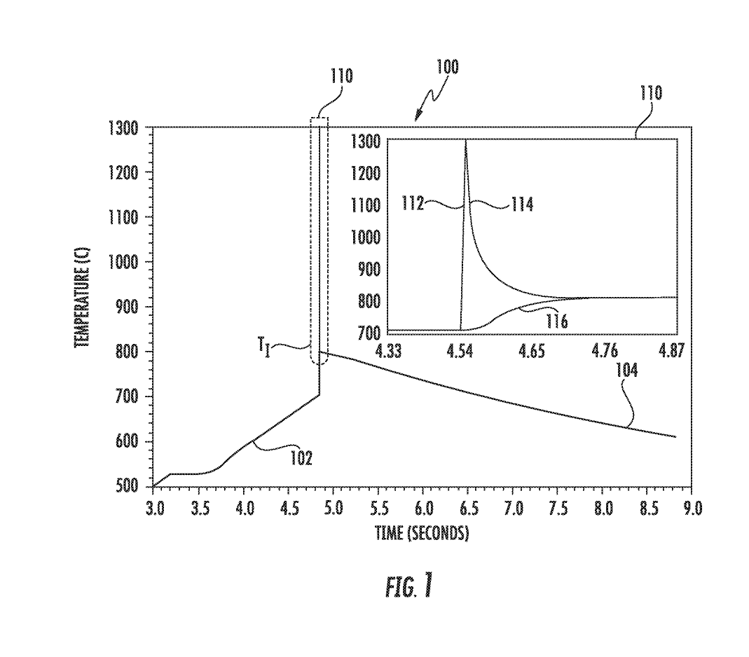

An example millisecond anneal system can be configured to provide an intense and brief exposure of light to heat the top surface of a wafer at rates that can exceed, for instance, about 10⁴° C./s. FIG. 1 depicts an example temperature profile 100 of a semiconductor substrate achieved using a millisecond anneal system. As shown in FIG. 1, the bulk of the semiconductor substrate (e.g., a silicon wafer) is heated to an intermediate temperature Tᵢ during a ramp phase 102. The intermediate temperature can be in the range of about 450° C. to about 900° C. When the intermediate temperature Tᵢ is reached, the top side of the semiconductor substrate can be exposed to a very short, intense flash of light resulting in heating rates of up to about 10⁴° C./s. Window 110 illustrates the temperature profile of the semiconductor substrate during the short, intense flash of light. Curve 112 represents the rapid heating of the top surface of the semiconductor substrate during the flash exposure. Curve 116 depicts the temperature of the remainder or bulk of the semiconductor substrate during the flash exposure. Curve 114 represents the rapid cool down by conductive of cooling of the top surface of the semiconductor substrate by the bulk of the semiconductor substrate acting as a heat sink. The bulk of the semiconductor substrate acts as a heat sink generating high top side cooling rates for the substrate. Curve 104 represents the slow cool down of the bulk of the semiconductor substrate by thermal radiation and convection, with a process gas as a cooling agent.

An example millisecond anneal system can include a plurality of arc lamps (e.g., four Argon arc lamps) as light sources for intense millisecond long exposure of the top surface of the semiconductor substrate—the so called “flash.” The flash can be applied to the semiconductor substrate when the substrate has been heated to an intermediate temperature (e.g., about 450° C. to about 900° C.). A plurality of continuous mode arc lamps (e.g., two Argon arc lamps) can be used to heat the semiconductor substrate to the intermediate temperature. In some embodiments, the heating of the semiconductor substrate to the intermediate temperature can be accomplished through the bottom surface of the semiconductor substrate at a ramp rate which heats the entire bulk of the wafer.

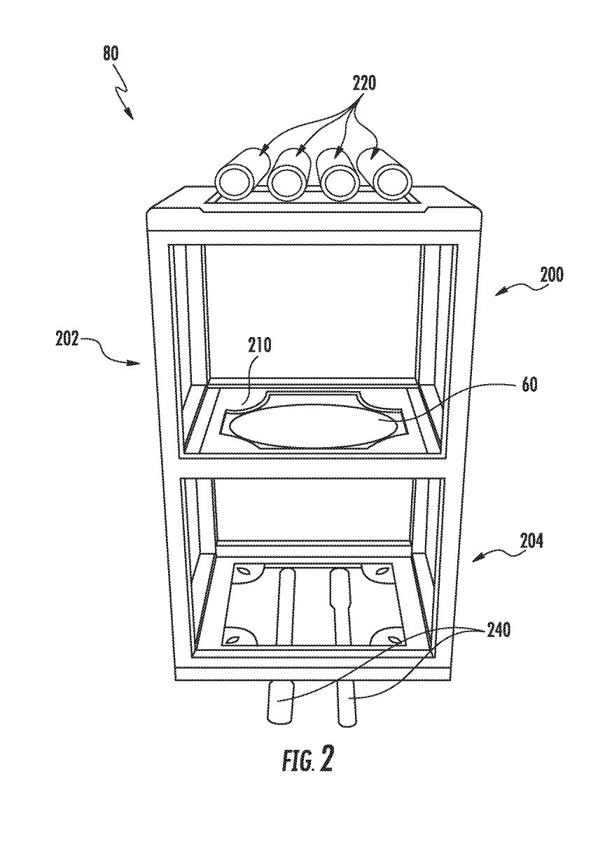

FIGS. 2 to 5 depict various aspects of an example millisecond anneal system 80 according to example embodiments of the present disclosure. As shown in FIGS. 2-4, a millisecond anneal system 80 can include a process chamber 200. The process chamber 200 can be divided by a wafer plane plate 210 into a top chamber 202 and a bottom chamber 204. A semiconductor substrate 60 (e.g., a silicon wafer) can be supported by support pins 212 (e.g., quartz support pins) mounted to a wafer support plate 214 (e.g., quartz glass plate inserted into the wafer plane plate 210).

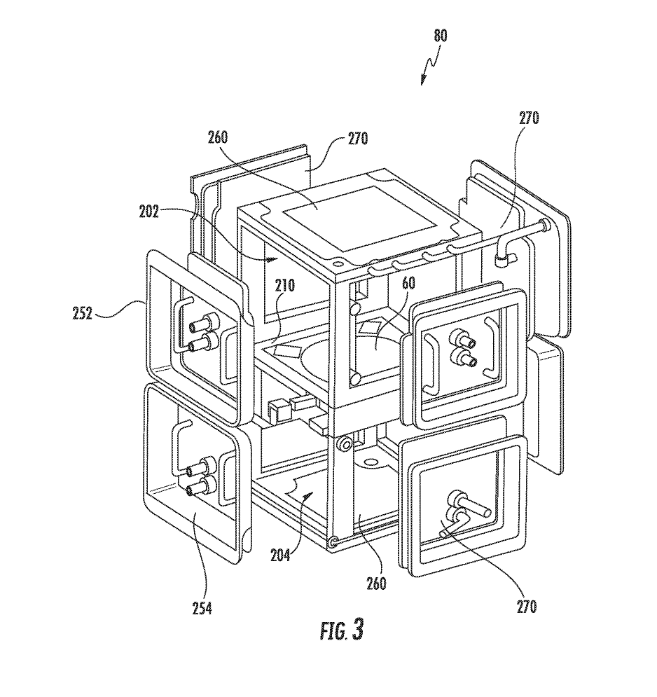

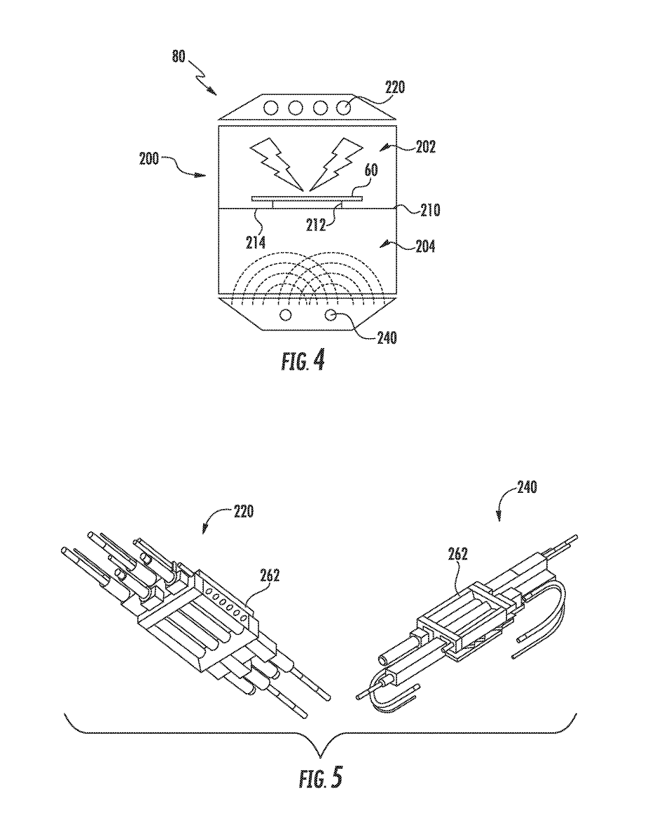

As shown in FIGS. 2 and 4, the millisecond anneal system 80 can include a plurality of arc lamps 220 (e.g., four Argon arc lamps) arranged proximate the top chamber 202 as light sources for intense millisecond long exposure of the top surface of the semiconductor substrate 60—the so called “flash.” The flash can be applied to the semiconductor substrate when the substrate has been heated to an intermediate temperature (e.g., about 450° C. to about 900° C.).

A plurality of continuous mode arc lamps 240 (e.g., two Argon arc lamps) located proximate the bottom chamber 204 can be used to heat the semiconductor substrate 60 to the intermediate temperature. In some embodiments, the heating of the semiconductor substrate 60 to the intermediate temperature is accomplished from the bottom chamber 204 through the bottom surface of the semiconductor substrate at a ramp rate which heats the entire bulk of the semiconductor substrate 60.

As shown in FIG. 3, the light to heat the semiconductor substrate 60 from the bottom arc lamps 240 (e.g., for use in heating the semiconductor substrate to an intermediate temperature) and from the top arc lamps 220 (e.g., for use in providing millisecond heating by flash) can enter the processing chamber 200 through water windows 260 (e.g., water cooled quartz glass windows). In some embodiments, the water windows 260 can include a sandwich of two quartz glass panes between which an about a 4 mm thick layer of water is circulating to cool the quartz panes and to provide an optical filter for wavelengths, for instance, above about 1400 nm.

As further illustrated in FIG. 3, process chamber walls 250 can include reflective mirrors 270 for reflecting the heating light. The reflective mirrors 270 can be, for instance, water cooled, polished aluminum panels. In some embodiments, the main body of the arc lamps used in the millisecond anneal system can include reflectors for lamp radiation. For instance, FIG. 5 depicts a perspective view of both a top lamp array 220 and a bottom lamp array 240 that can be used in the millisecond anneal system 200. As shown, the main body of each lamp array 220 and 240 can include a reflector 262 for reflecting the heating light. These reflectors 262 can form a part of the reflecting surfaces of the process chamber 200 of the millisecond anneal system 80.

The temperature uniformity of the semiconductor substrate can be controlled by manipulating the light density falling onto different regions of the semiconductor substrate. In some embodiments, uniformity tuning can be accomplished by altering the reflection grade of small size reflectors to the main reflectors and/or by use of edge reflectors mounted on the wafer support plane surrounding the wafer.

For instance, edge reflectors can be used to redirect light from the bottom lamps 240 to an edge of the semiconductor substrate 60. As an example, FIG. 6 depicts example edge reflectors 264 that form a part of the wafer plane plate 210 that can be used to direct light from the bottom lamps 240 to the edge of the semiconductor substrate 60. The edge reflectors 264 can be mounted to the wafer plane plate 210 and can surround or at least partially surround the semiconductor substrate 60.

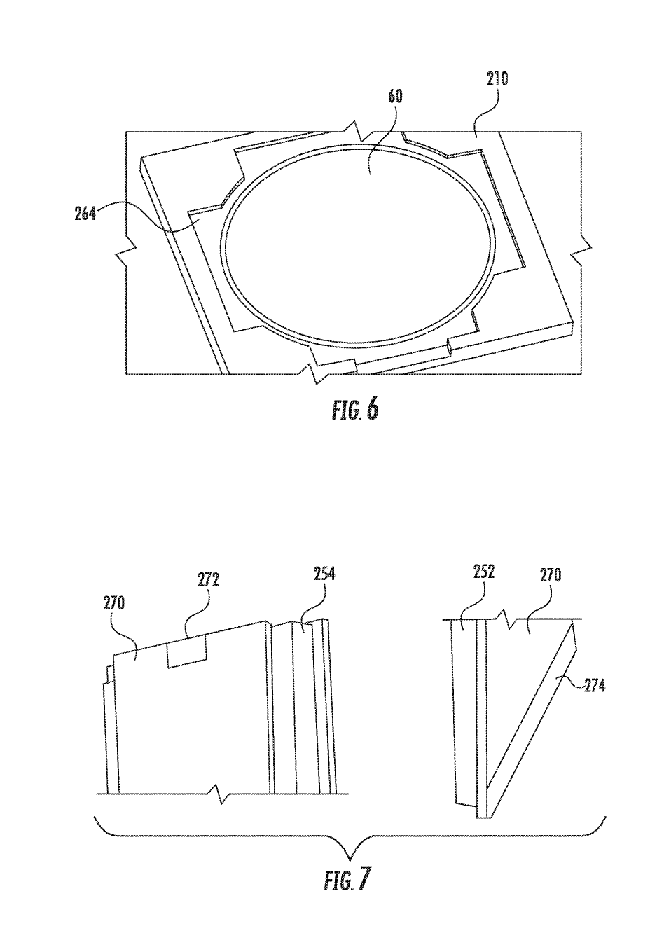

In some embodiments, additional reflectors can also be mounted on chamber walls near the wafer plane plate 210. For example, FIG. 7 depicts example reflectors that can be mounted to the process chamber walls that can act as reflector mirrors for the heating light. More particularly, FIG. 7 shows an example wedge reflector 272 mounted to lower chamber wall 254. FIG. 7 also illustrates a reflective element 274 mounted to reflector 270 of an upper chamber wall 252. Uniformity of processing of the semiconductor substrate 60 can be tuned by changing the reflection grade of the wedge reflectors 272 and/or other reflective elements (e.g., reflective element 274) in the processing chamber 200.

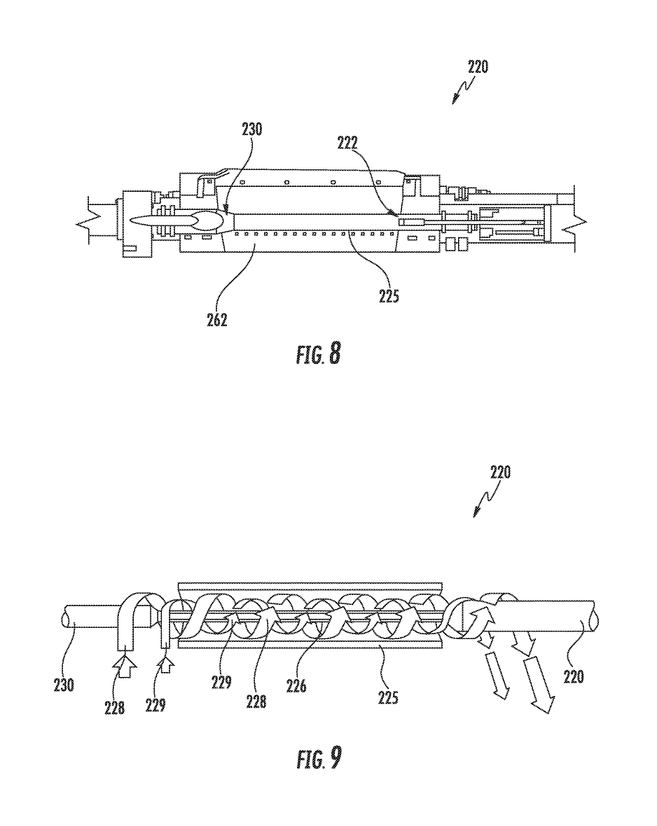

FIGS. 8-11 depict aspects of example upper arc lamps 220 that can be used as light sources for intense millisecond long exposure of the top surface of the semiconductor substrate 60 (e.g., the “flash”). For instance, FIG. 8 depicts a cross-sectional view of an example arc lamp 220. The arc lamp 220 can be, for instance, an open flow arc lamp, where pressurized Argon gas (or other suitable gas) is converted into a high pressure plasma during an arc discharge. The arc discharge takes place in a quartz tube 225 between a negatively charged cathode 222 and a spaced apart positively charged anode 230 (e.g., spaced about 300 mm apart). As soon as the voltage between the cathode 222 and the anode 230 reaches a breakdown voltage of Argon (e.g., about 30 kV) or other suitable gas, a stable, low inductive plasma is formed which emits light in the visible and UV range of the electromagnetic spectrum. As shown in FIG. 9, the lamp can include a lamp reflector 262 that can be used to reflect light provided by the lamp for processing of the semiconductor substrate 60.

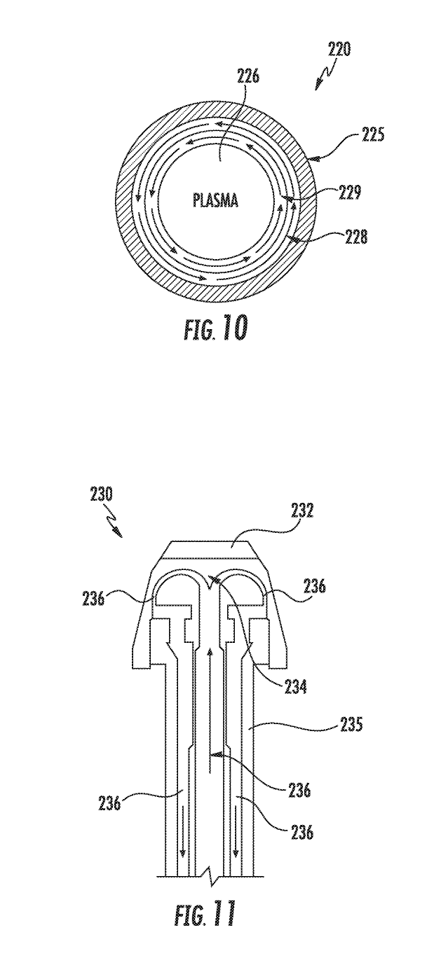

FIGS. 10 and 11 depict aspects of example operation of an arc lamp 220 in millisecond anneal system 80 according to example embodiments of the present disclosure. More particularly, a plasma 226 is contained within a quartz tube 225 which is water cooled from the inside by a water wall 228. The water wall 228 is injected at high flow rates on the cathode end of the lamp 200 and exhausted at the anode end. The same is true for the Argon gas 229, which is also entering the lamp 220 at the cathode end and exhausted from the anode end. The water forming the water wall 228 is injected perpendicular to the lamp axis such that the centrifugal action generates a water vortex. Hence, along the center line of the lamp a channel is formed for the Argon gas 229. The Argon gas column 229 is rotating in the same direction as the water wall 228. Once a plasma 226 has formed, the water wall 228 is protecting the quartz tube 225 and confining the plasma 226 to the center axis. Only the water wall 228 and the electrodes (cathode 230 and anode 222) are in direct contact with the high energy plasma 226.

FIG. 11 depicts a cross sectional view of an example electrode (e.g., cathode 230) used in conjunction with an arc lamp according to example embodiments of the present disclosure. FIG. 11 depicts a cathode 230. However, a similar construction can be used for the anode 222.

In some embodiments, as the electrodes experience a high heat load, one or more of the electrodes can each include a tip 232. The tip can be made from tungsten. The tip can be coupled to and/or fused to a water cooled copper heat sink 234. The copper heat sink 234 can include at least a portion the internal cooling system of the electrodes (e.g., one or more water cooling channels 236. The electrodes can further include a brass base 235 with water cooling channels 236 to provide for the circulation of water or other fluid and the cooling of the electrodes.

The arc lamps used in example millisecond anneal systems according to aspects of the present disclosure can be an open flow system for water and Argon gas. However, for conservation reasons, both media can be circulated in a close loop system in some embodiments. In some embodiments, nitrogen gas can be injected into the arc lamp during operation to control the pH of water circulating through the arc lamp during operation. An example water loop system will be discussed in detail with respect to FIG. 14.

Millisecond anneal systems according to example embodiments of the present disclosure can include the ability to independently measure temperature of both surfaces (e.g., the top and bottom surfaces) of the semiconductor substrate. FIG. 13 depicts an example temperature measurement system 150 for millisecond anneal system 200.

A simplified representation of the millisecond anneal system 200 is shown in FIG. 13. The temperature of both sides of a semiconductor substrate 60 can be measured independently by temperature sensors, such as temperature sensor 152 and temperature sensor 154. Temperature sensor 152 can measure a temperature of a top surface of the semiconductor substrate 60. Temperature sensor 154 can measure a bottom surface of the semiconductor substrate 60. In some embodiments, narrow band pyrometric sensors with a measurement wavelength of about 1400 nm can be used as temperature sensors 152 and/or 154 to measure the temperature of, for instance, a center region of the semiconductor substrate 60. In some embodiments, the temperature sensors 152 and 154 can be ultra-fast radiometers (UFR) that have a sampling rate that is high enough to resolve the millisecond temperature spike cause by the flash heating.

The readings of the temperature sensors 152 and 154 can be emissivity compensated. As shown in FIG. 14, the emissivity compensation scheme can include a diagnostic flash 156, a reference temperature sensor 158, and the temperature sensors 152 and 154 configured to measure the top and bottom surface of the semiconductor substrates. Diagnostic heating and measurements can be used with the diagnostic flash 156 (e.g., a test flash). Measurements from reference temperature sensor 158 can be used for emissivity compensation of temperature sensors 152 and 154

In some embodiments, the millisecond anneal system 200 can include water windows. The water windows can provide an optical filter that suppresses lamp radiation in the measurement band of the temperature sensors 152 and 154 so that the temperature sensors 152 and 154 only measure radiation from the semiconductor substrate.

The readings of the temperature sensors 152 and 154 can be provided to a processor circuit 160. The processor circuit 10 can be located within a housing of the millisecond anneal system 200, although alternatively, the processor circuit 160 may be located remotely from the millisecond anneal system 200. The various functions described herein may be performed by a single processor circuit if desired, or by other combinations of local and/or remote processor circuits.

### Example Lamp Electrode Tip in a Millisecond Anneal System

According to example aspects of the present disclosure, the life of an anode, cathode or other electrode used in arc lamps can be extended by mitigating the material loss of molten tungsten. The lifetime of the electrode can be directly correlated to the loss rate of molten tungsten in the center of the electrode tip. According to example aspects of the present disclosure, the geometry of the electrode is configured to locally keep tungsten in the center of the tip and prevent transport from the center to the tip edge. An additional effect can be to prevent the large bead formation on the edge perimeter of the tip, thus maintaining an undisturbed flow pattern around the anode.

In one example embodiment of the present disclosure, the transport of molten tungsten is reduced by modifying the geometry of the tungsten tip surface such that the surface includes one or more circular grooves. A purpose of the circular grooves can be to keep the bead formation localized and act as a barrier to the lateral transport of molten material. Hence, the transport of material is limited by way of the surface structure. The transport is reduced until the molten drop reaches a critical size, at which time the aerodynamical forces dominate the adhesion forces, and the drop flows over the barrier. Bead size can be automatically lowered by the flow action and the process can repeat itself at the next barrier. As a result, the dwell time of the molten material can be extended over the nominal case with flat surface structure.

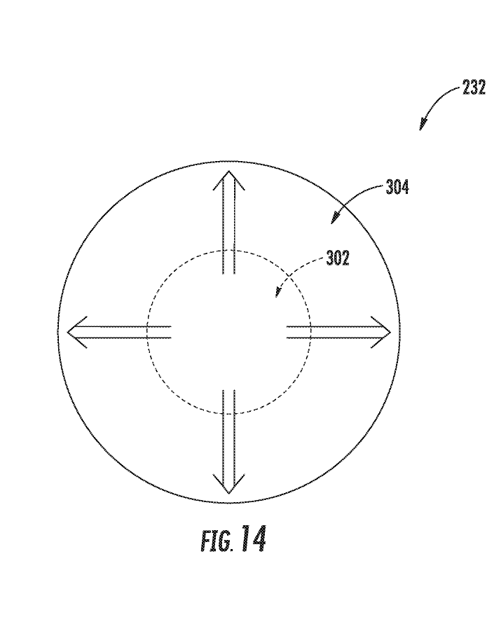

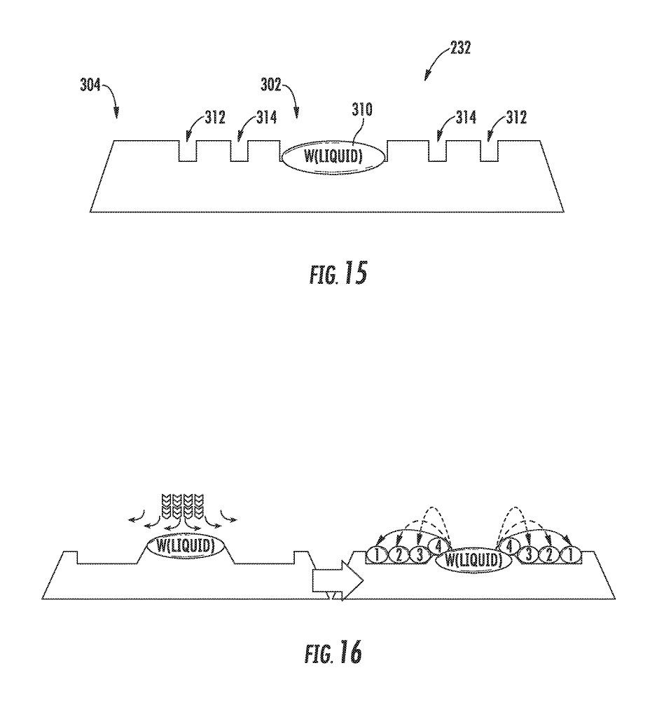

FIG. 15 depicts a surface of an electrode tip 232 used in an arc lamp according to example embodiments of the present disclosure. As shown, the surface of the electrode tip includes a plurality of concentric circular grooves 312 and 314. The rim of the circular grooves 312 and 312 can act as a barrier to the flow of molten material 310 (e.g., molten Tungsten) across the surface of the electrode 232, for instance, from a center portion 302 to a lateral portion 304.

FIG. 16 depicts the effect of the rim of the grooves acting as a barrier to the flow of molten material. More particularly, after a number of heat cycles, a critical-sized tungsten drop can be transported to the edge. The drop numbers, 1, 2, 3, and 4 in FIG. 16 can indicate the generation of solidified drops during transport of molten tungsten.

In the embodiment of FIG. 16, there is a single groove 312 formed in the surface of the electrode tip 312. The transport limitation is brought about by the solidification of drops from previous heat cycles (e.g., the center of the tip is surrounded by a wall of older generations of beads.) FIG. 16 depicts the effect of the rim of the groove 312 acting as a barrier to the flow of molten material. More particularly, after a number of heat cycles, a critical-sized tungsten drop is being transported to the edge. The numbers, 1, 2, 3, and 4 indicate the generation of solidified drops.

The surface of an electrode tip according to example aspects of the present disclosure can have a variety of different groove patterns to impair the lateral flow of molten material from a center portion of the electrode tip to an edge portion of the electrode tip. For instance, in some embodiments, the electrode tip can include concentric circular grooves. In some embodiments, the concentric circular grooves are not equidistant from the center of the electrode tip.

In some embodiments, the groove pattern can include a plurality of intersecting linear grooves disposed across a surface of the electrode tip. The plurality of intersecting linear grooves can form a grid of lines. The intersecting angle between the grooves can be, for instance, in the range of about 10° to 180°.

FIG. 17 depicts an example electrode tip 232 having a plurality of intersecting linear grooves 320. The linear grooves 320 intersect one another at an about a 90° intersecting angle. The linear grooves 320 form a square grid pattern.

FIG. 18 depicts an example electrode tip 232 having a plurality of intersecting linear grooves 330. The linear grooves 330 intersect one another at an about a 60° intersecting angle. The linear grooves 330 form a triangular grid pattern.

In some embodiments, a shape of the tungsten-copper interface between an electrode tip and a heat sink of an electrode used in an arc lamp is designed to influence the lateral temperature distribution across the electrode tip. The lateral heat distribution across the surface of an electrode tip can have impact on the lifetime of the anode by reducing the flow of molten material across the surface, and by reducing the heat load density.

To provide for reducing the flow of molten material across the surface of the electrode tip, a large lateral temperature gradient can be desired, with the edge of the tip being much colder than the center of the tip. In the case where the edge of the tip remains below the melting point of tungsten, the lateral transport of molten material can be inhibited, and the drops and beads can remain localized in the center.

To provide for reducing the heat load density, a low lateral temperature gradient can be desired. With a low temperature gradient, the heat load is evenly distributed across the tip surface and local overheating is mitigated.

The lateral temperature distribution across the surface of the electrode tip can a function of the amount of heat conducted through the electrode tip. The thermal conductivity can be a function of the distance between the surface of the electrode tip and the interface between the electrode tip and a heat sink coupled to the electrode tip. For a flat interface, the distance for the heat conduction is increasing center to edge for geometric reasons. For a concave shaped interface, the increase in distance is smaller from center to edge, hence the temperature gradient is lower. The reverse is true for a convex shaped interface.

According to example aspects of the present disclosure, the interface between electrode tip (e.g., tungsten electrode tip) and the heat sink (e.g., the copper heat sink) is facetted or rounded.

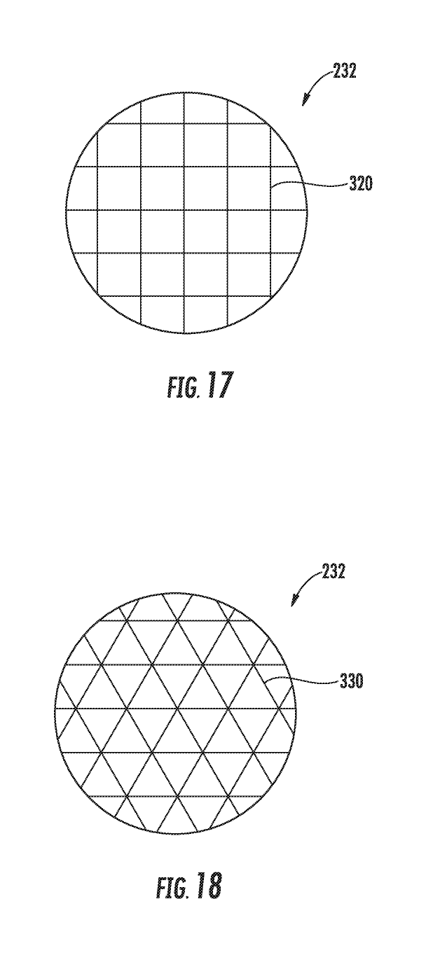

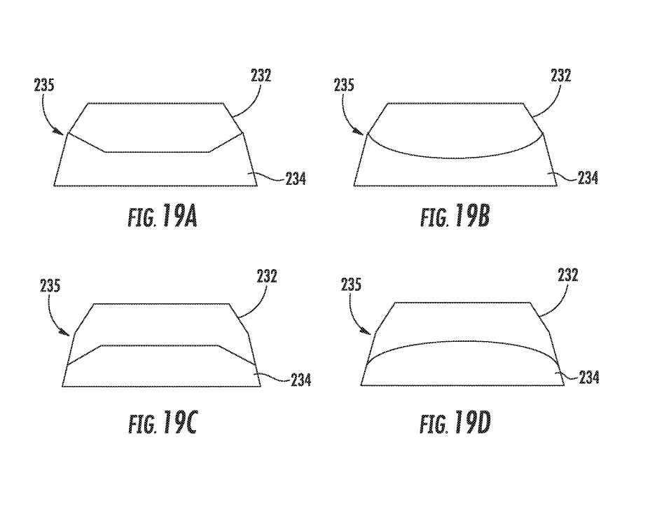

FIG. 19 depicts examples shapes of the tungsten-copper interface to influence lateral temperature distribution according to example aspects of the present disclosure. FIG. 19(a) depicts a faceted, concave interface 235 between the electrode tip 232 and the heat sink 234. The interface 235 of FIG. 19(a) can be configured to decrease a temperature gradient across a surface of the electrode tip 232. FIG. 19(b) depicts a rounded, concave interface 235 between the electrode tip 232 and the heat sink 234. The interface 235 of FIG. 19(b) can be configured to decrease a temperature gradient across a surface of the electrode tip 232. FIG. 19(c) depicts a faceted, convex interface 235 between the electrode tip 232 and the heat sink 234. The interface 235 of FIG. 19(c) can be configured to increase a temperature gradient across a surface of the electrode tip 232, with lower temperature on the edge and higher temperature in the center. FIG. 29(d) depicts a rounded, convex interface 235 between the electrode tip 232 and the heat sink 234. The interface 235 of FIG. 19(d) can be configured to increase a temperature gradient across a surface of the electrode tip 232, with lower temperature on the edge and higher temperature in the center.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A millisecond anneal system, comprising:
a processing chamber for thermally treating a semiconductor substrate using a millisecond anneal process;
one or more arc lamp heat sources, each of the one or more arc lamp heat sources comprising a plurality of electrodes for generating an arc through a gas in the arc lamp to generate a plasma;
wherein at least one of the plurality of electrodes has an electrode tip having a surface with at least one groove to reduce lateral transportation of molten material across the surface of the electrode tip.

2. The millisecond anneal system of claim 1, wherein the at least one groove has a rim configured to act as a barrier to reduce the lateral transportation of molten material across the surface of the electrode tip.

3. The millisecond anneal system of claim 1, wherein the at least one groove comprises a circular groove.

4. The millisecond anneal system of claim 1, wherein the at least one groove comprises a plurality of concentric circular grooves.

5. The millisecond anneal system of claim 1, wherein the at least one groove is one of a plurality of intersecting linear grooves.

6. The millisecond anneal system of claim 5, wherein the intersecting linear grooves form a square grid pattern.

7. The millisecond anneal system of claim 5, wherein the intersecting linear grooves form a triangular grid pattern.

8. The millisecond anneal system of claim 1, wherein the electrode tip is formed from tungsten.

9. The millisecond anneal system of claim 1, wherein the electrode has an interface between the electrode tip and a heat sink, the interface having a concave shape.

10. The millisecond anneal system of claim 1, wherein the electrode has an interface between the electrode tip and a heat sink, the interface having a convex shape.

11. An arc lamp, comprising:
a plurality of electrodes; and
one or more inlets configured to receive water to be circulated through the arc lamp during operation, the one or one or more inlets configured to receive a gas, wherein during operation of the arc lamp, the gas is converted into a plasma during an arc discharge between the plurality of electrodes;
wherein at least one of the plurality of electrodes has an electrode tip, the electrode tip having a surface with at least one groove to reduce lateral transportation of molten material across the surface of the electrode tip.

12. The arc lamp of claim 11, wherein the at least one groove comprises a circular groove.

13. The arc lamp of claim 11, wherein the at least one groove comprises a plurality of concentric circular grooves.

14. The arc lamp of claim 11, wherein the at least one groove is one of a plurality of intersecting linear grooves.

15. An arc lamp, comprising:
a plurality of electrodes; and
one or more inlets configured to receive water to be circulated through the arc lamp during operation, the one or one or more inlets configured to receive a gas, wherein during operation of the arc lamp, the gas is converted into a plasma during an arc discharge between the plurality of electrodes;
wherein at least one of the plurality of electrodes has an electrode tip and a heat sink, wherein the electrode has an interface between the electrode tip and the heat sink, the interface being concave or convex.

16. The arc lamp of claim 15, wherein the interface is a rounded concave interface.

17. The arc lamp of claim 15, wherein the interface is a faceted concave interface.

18. The arc lamp of claim 15, wherein the interface is a rounded convex interface.

19. The arc lamp of claim 15, wherein the interface is a faceted convex interface.

20. The arc lamp of claim 15, wherein the electrode tip comprises tungsten and the heat sink comprises copper.
